(19) United States
(12) Patent Application Publication
(10) Pub. No.: US 2025/0293060 A1
(43) Pub. Date: Sep. 18, 2025

(54) PRESSURE CONTROL METHOD AND APPARATUS, AND SEMICONDUCTOR PROCESS DEVICE

(71) Applicant: BEIJING AURASKY ELECTRONICS CO., LTD., Beijing (CN)

(72) Inventors: Wenning ZHENG, Beijing (CN); Di ZHAO, Beijing (CN); Chuanzheng DU, Beijing (CN)

(21) Appl. No.: 18/869,205

(22) PCT Filed: May 26, 2023
(86) PCT No.: PCT/CN2023/096498

§ 371 Date: Nov. 25, 2024

(30) Foreign Application Priority Data
May 30, 2022 (CN) 202210602647.6

(51) Int. Cl. H01L 21/67; G05D 16/20

(52) U.S. Cl. CPC H01L 21/67253; G05D 16/2026

(57) ABSTRACT

There are provided a pressure control method and apparatus and a semiconductor process device. The method includes: acquiring an actual pressure value in a process chamber in real time (S1); calculating a pressure variation of the actual pressure value (S2); and comparing the pressure variation with a preset value set in advance, controlling, in a case where the pressure variation is less than or equal to the preset value, an actuator of a pressure regulating valve to maintain a current frequency, controlling, in a case where the pressure variation is greater than the preset value, a frequency of the actuator to decrease according to a preset functional relationship until the actual pressure value reaches a target pressure value (S3), and controlling an opening change of the pressure regulating valve based on the frequency. The method solves a problem of pressure overshoot in a rapid control process of a chamber pressure, and reduces an influence of a pressure fluctuation on the process.

### TECHNICAL FIELD

The present disclosure relates to the technical field of semiconductor manufacturing, and in particular, to a pressure control method and apparatus, and a semiconductor process device.

### BACKGROUND

In the fields of semiconductor manufacturing and photovoltaics, a process chamber such as a process chamber of an oxidation furnace is one of the most important devices in a semiconductor process. H₂, HCL, excessive O₂, a small amount of C₂H₂Cl₂, and N₂ entering the process chamber of the oxidation furnace need to perform chemical reaction under a constant pressure, so as to ensure that a thickness of a plating layer meets a requirement. Since the thickness of the plating layer may be affected when a pressure in the process chamber is greater than or less than a set pressure, the pressure in the process chamber needs to be kept stable. How to accurately and quickly control the pressure in the chamber becomes a key technical problem to be solved.

In the prior art, the Chinese patent application with the publication number of CN111831022A proposed a chamber pressure control method, which may realize rapid pressure control based on a Pressure To Location (PTL) strategy. Such method adopts the PTL strategy based on a quick-opening characteristic of a pressure regulating valve, that is, a closed-loop Proportional-Integral-Derivative (PID) control coefficient is dynamically and autonomously adjusted, and a calculation is performed based on a PTL conversion coefficient Kn (a conversion coefficient between a pressure change and an opening of a butterfly valve) and the PID coefficient, so as to realize PID fine adjustment, thereby achieve the purpose of controlling the pressure rapidly and stably.

Although such method may control the pressure rapidly, that is, a quick response may be given when relevant parameters (such as flow and pressure) are changed during the process, quick adjustment can easily cause an overshoot phenomenon due to a hysteresis characteristic of a pressure system, and a fluctuation in the pressure in the chamber caused by the overshoot may affect a process result.

### SUMMARY

The present disclosure provides a pressure control method and apparatus and a semiconductor process device, so as to solve a problem of pressure overshoot in a rapid control process of a chamber pressure, and reduce an influence of a pressure fluctuation on the process.

In a first aspect, the present disclosure provides a pressure control method applied to a process chamber of a semiconductor process device, a gas pipeline of the process chamber being provided with a pressure regulating valve for regulating a pressure in the process chamber, and the method includes:
acquiring an actual pressure value in the process chamber in real time;
calculating a pressure variation of the actual pressure value; and
comparing the pressure variation with a preset value set in advance; in a case where the pressure variation is less than or equal to the preset value, controlling an actuator of the pressure regulating valve to maintain a current frequency, and controlling an opening change of the pressure regulating valve based on the current frequency; and in a case where the pressure variation is greater than the preset value, controlling a frequency of the actuator to decrease according to a preset functional relationship, and controlling the opening change of the pressure regulating valve based on the frequency.

Optionally, calculating the pressure variation of the actual pressure value includes:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to a maximum difference between an initial actual pressure value in the process chamber and the target pressure value as the pressure variation.

Optionally, calculating the pressure variation of the actual pressure value includes:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to the first difference as the pressure variation.

Optionally, controlling the frequency of the actuator to decrease according to the preset functional relationship includes:
calculating a difference between each acquired actual pressure value and a target pressure value; and
in a case where the difference is greater than zero, controlling the frequency of the actuator to decrease according to the preset functional relationship, with the preset functional relationship meeting that differences corresponding to all actual pressure values correspond to frequencies of the actuator in a one-to-one correspondence manner.

Optionally, the preset functional relationship is: Fᵢ₊₁=K×Fᵢ, where Fᵢ is the current frequency of the actuator, Fᵢ₊₁ is a next frequency of the actuator, a value of K is between 0 and 1, and i=1, 2, 3, . . . , n, wherein F₁ is an initial frequency of the actuator, and the initial frequency is a maximum frequency at which the actuator does not produce resonance.

Optionally, controlling the opening change of the pressure regulating valve based on the frequency includes:
according to the acquired actual pressure value and a target pressure value set in advance, controlling the opening change of the pressure regulating valve with a Proportional-Integral-Derivative (PID) closed-loop control method.

Optionally, the actual pressure value is an absolute pressure value inside the process chamber; or
the actual pressure value is a relative value between the pressure inside the process chamber and the atmospheric pressure.

In a second aspect, the present disclosure provides a chamber pressure control apparatus, including: a pressure collector, a pressure controller, and an actuator;
the pressure collector is configured to collect an actual pressure value in a process chamber in real time;
the pressure controller is configured to perform the pressure control method described in the first aspect; and
the actuator is configured to control an opening change of a pressure regulating valve based on a frequency output by the pressure controller.

Optionally, the actuator is a motor for controlling the opening change of the pressure regulating valve, and a frequency of the actuator is a rotation frequency of the motor.

Optionally, the pressure regulating valve includes an elastic telescopic member, so as to perform opening adjustment with the elastic telescopic member.

In a second aspect, the present disclosure provides a semiconductor process device, including a process chamber, and a pressure regulating valve provided on a gas pipeline of the process chamber, and the semiconductor process device further includes the chamber pressure control apparatus described in the second aspect.

The present disclosure has the following beneficial effects.

In the pressure control process according to the present disclosure, the actual pressure value in the process chamber is acquired in real time, the pressure variation of the actual pressure value is calculated and is compared with the preset value set in advance, the actuator of the pressure regulating valve is controlled to maintain the current frequency and the opening change of the pressure regulating valve is controlled based on the current frequency in the case where the pressure variation is less than or equal to the preset value; and the frequency of the actuator is controlled to decrease according to the preset functional relationship and the opening change of the pressure regulating valve is controlled based on the frequency in the case where the pressure variation is greater than the preset value. During the pressure control process, the frequency of the actuator is gradually reduced as the difference between the actual pressure value and the target pressure value gradually decreases, that is, a rate of the opening change of the pressure regulating valve is gradually reduced as the pressure difference gradually decreases, so that a pressure overshoot phenomenon caused by a pressure change or a flow change during the pressure control process can be effectively reduced, and quick pressure control response and stable pressure control can be realized. When the gas flow in a pressure control system of the process chamber is continuously and gradually reduced or increased within a specified period of time, the method provided herein has a significant effect on avoiding the pressure overshoot, thereby improving process quality.

The apparatus provided herein has other features and advantages, which will become apparent from the accompanying drawings and the following specific implementations or will be described in detail with reference to the accompanying drawings and the following specific implementations. The drawings together with the specific implementations are used to explain certain principles of the present disclosure.

### BRIEF DESCRIPTION OF DRAWINGS

The above and other objectives, features and advantages of the present disclosure will become more apparent from the description of exemplary embodiments of the present disclosure with reference to the accompanying drawings. In the exemplary embodiments of the present disclosure, the same reference numeral generally denotes the same element.

FIG. 1 is a flowchart illustrating a pressure control method according to Embodiment One of the present disclosure.

FIG. 2 is a curve graph illustrating changes of a frequency of an actuator and a pressure in a pressure control method according to Embodiment One of the present disclosure.

FIG. 3 is a schematic diagram illustrating a principle of a chamber pressure control apparatus according to Embodiment Two of the present disclosure.

FIG. 4 is a schematic structural diagram of a semiconductor process device according to Embodiment Three of the present disclosure.

### DETAIL DESCRIPTION OF EMBODIMENTS

In order to solve the technical problems in the prior art, the present disclosure provides a pressure control method and apparatus, and a semiconductor process device. Based on an input-output negative feedback characteristic of a pressure system, the pressure control method changes a frequency of an actuator step by step in a whole pressure closed-loop control process, so that a problem of pressure overshoot in a rapid chamber pressure control process can be solved, and an influence of a pressure fluctuation on the process can be reduced to the greatest extent. The pressure control method can be applied to different pressure control systems.

The present disclosure will be described in detail below with reference to the drawings. Although the drawings show the preferable embodiments of the present disclosure, it should be understood that the present disclosure may be implemented in various forms and should not be limited to the embodiments described herein. On the contrary, the embodiments are provided to make the present disclosure more thorough and complete and fully convey the scope of the present disclosure to those of ordinary skill in the art.

### Embodiment One

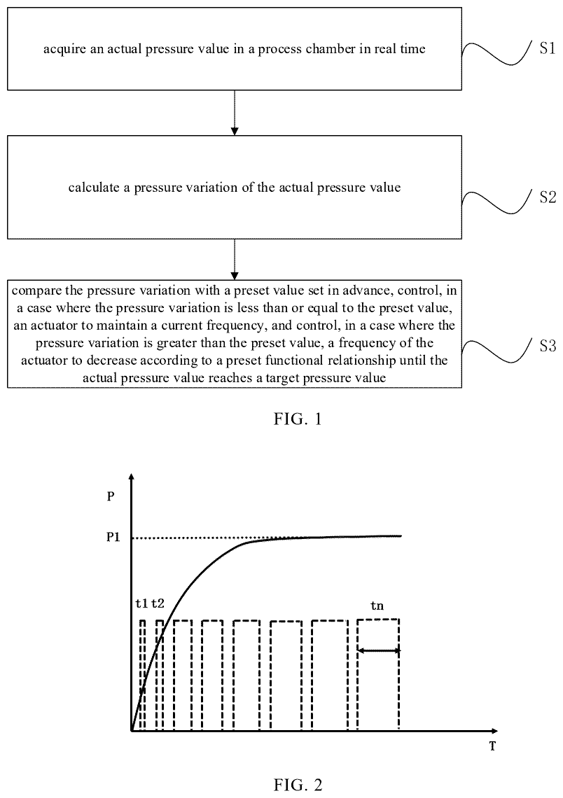

As shown in FIG. 1, a pressure control method specifically includes the following steps S1, S2, and S3.

S1: acquiring an actual pressure value in a process chamber in real time.

Optionally, the actual pressure value is an absolute pressure value inside the process chamber, for example, a pressure at an exhaust port of the process chamber may be detected and taken as the actual pressure value; or, the actual pressure value is a relative value between a pressure inside the process chamber and the atmospheric pressure. Therefore, the chamber pressure control method provided in the present embodiment can be applied to an absolute pressure control method or a relative pressure control method.

S2: calculating a pressure variation of the actual pressure value.

S3: comparing the pressure variation with a preset value set in advance; in a case where the pressure variation is less than or equal to the preset value, controlling an actuator of a pressure regulating valve to maintain a current frequency, and controlling an opening change of the pressure regulating valve based on the current frequency; and in a case where the pressure variation is greater than the preset value, controlling a frequency of the actuator to decrease according to a preset functional relationship, and controlling the opening change of the pressure regulating valve based on the frequency.

In the present embodiment, at step S3, controlling the opening change of the pressure regulating valve based on the frequency includes:
controlling the opening change of the pressure regulating valve with a PID closed-loop control method according to the acquired actual pressure value and a target pressure value set in advance until the actual pressure value reaches the target pressure value.

Specifically, the actual pressure value in the process chamber is acquired in real time at step S1, and is compared with the target pressure value set in advance, and when the actual pressure value does not reach the target pressure value, the opening change of the pressure regulating valve is controlled with the PID closed-loop control method until the actual pressure value reaches the target pressure value. Since the PID closed-loop control method is well known in the art, the PID closed-loop control method will not be described in detail here.

Moreover, before performing closed-loop control on the pressure in the chamber, the pressure variation of the actual pressure value is calculated and compared with the preset value set in advance, and then it is determined according to a comparison result whether to control the actuator to maintain the current frequency or control the frequency of the actuator to decrease according to the preset functional relationship in a process of performing closed-loop control on the pressure in the chamber, so that the frequency of the actuator can be adaptively adjusted by taking the pressure variation as a judgment basis, thereby effectively reducing a pressure overshoot phenomenon caused by a pressure change or a flow change during the pressure control process, and realizing quick pressure control response and stable pressure control.

In some alternative embodiments, at step S2, calculating the pressure variation of the actual pressure value includes:
calculating a first difference between a first actual pressure value in the process chamber which is acquired at a first moment and the target pressure value;
calculating a second difference between a second actual pressure value in the process chamber which is acquired at a second moment and the target pressure value; and
calculating a ratio of a difference between the first difference and the second difference to a maximum difference between an initial actual pressure value in the process chamber and the target pressure value, or, taking a ratio of the difference between the first difference and the second difference to the first difference as the pressure variation.

The initial actual pressure value in the process chamber refers to an actual pressure value in the process chamber which is acquired at an initial moment of performing closed-loop control on the pressure in the chamber. Since the actual pressure value in the process chamber gradually approaches and finally reaches the target pressure value while performing closed-loop control on the pressure in the chamber, the difference between the initial actual pressure value and the target pressure value is the maximum one among differences between all the acquired actual pressure values and the target pressure value, and is referred to as “the maximum difference between the initial actual pressure value and the target pressure value”.

Specifically, the initial actual pressure value in the process chamber may be acquired with a pressure sensor, and the target pressure value is a pressure value required by the process and is a set value. In addition, at the initial moment of performing closed-loop control on the pressure in the chamber, a frequency of the actuator is an initial frequency, which may be determined based on the above maximum difference. The initial frequency may be set according to empirical values in practical applications, for example, the initial frequency may be set to be the maximum frequency at which the actuator does not produce resonance.

In some alternative embodiments, at step S3, the preset functional relationship is: Fᵢ₊₁=K×Fᵢ, where Fᵢ is the current frequency of the actuator, Fᵢ₊₁ is a next frequency of the actuator, a value of K is between 0 and 1, and i=1, 2, 3, . . . , n. F₁ is the initial frequency of the actuator, and the initial frequency is the maximum frequency at which the actuator does not produce resonance.

For example, the pressure variation (a change value of a real-time difference relative to the maximum pressure difference) for each frequency conversion may be a certain proportion of the difference between the actual pressure value in the process chamber which is actually measured and the set target pressure value. The smaller the preset value of the pressure variation which is configured to be compared with the pressure variation is, the more frequently the frequency of the actuator is adjusted, so that smooth frequency conversion may be realized, and the overshoot phenomenon may be avoided when the frequency is changed step by step during frequency conversion in a specific occasion. For example, the preset value of the pressure variation is set to be 5%, that is, the pressure variation needs to be greater than 5% for a next frequency conversion process to be performed. A frequency conversion degree may be set according to actual situations, for example, the frequency of the actuator is adjusted to 10% of a previous frequency each time. The frequency of the actuator may be specifically adjusted in the following two ways.

Way One: the frequency of the actuator is determined according to a change value (i.e., an absolute pressure change value) of the difference between the actual pressure value acquired in real time and the target pressure value relative to the maximum difference. For example, Pn is the target pressure value, P1 is the initial pressure value, P2 and P3 are the actual pressure values sequentially acquired at intermediate moments, and the differences between the actual pressure values acquired at the different moments and the target pressure value are ΔP1=Pn−P1, ΔP2=Pn−P2, and ΔP3=Pn−P3.

In a case where an absolute pressure variation is (ΔP1−ΔP2)/ΔP1>5%, the initial frequency F₁ is executed within a pressure change range from P1 to P2, and the executed frequency is adjusted, after P2, to F₂=10%×F₁.

If a case where the absolute pressure variation is (ΔP1−ΔP2)/ΔP1≤5%, the executed frequency is maintained at the current frequency F₁ after P2 is reached.

Way Two: the frequency of the actuator may be determined according to a change value (i.e., a relative pressure change value) of the difference between the actual pressure value acquired currently and the target pressure value relative to a previous difference.

The case of (ΔP1−ΔP2)/ΔP1>5% or (ΔP1−ΔP2)/ΔP1≤5% will not be described in detail here.

The above are just examples, 5% is just a self-set threshold (i.e., the preset value), and the actuator may operate at the current frequency in the case of less than 5%. In addition, a frequency conversion value of the actuator may be customized according to actual needs, 10% is just for illustration, and the frequency conversion value may be specifically adjusted according to response time. The longer the time consumed when the difference between the actual pressure value and the target pressure value gradually decreases from the maximum difference until the actual pressure value reaches the set target pressure value, the larger the frequency conversion degree.

It should be noted that the actuator is a motor of the pressure regulating valve, and the frequency of the actuator is a rotation frequency of the motor. The smaller the difference between the actual pressure value in the process chamber and the target pressure value is, the lower the corresponding rotation speed of the motor is, that is, the smaller the operating rate of a valve of the pressure regulating valve is, the more slowly the opening of the valve is changed. Therefore, the smaller the difference is, the more stably the valve operates.

By use of the input-output negative feedback characteristic of the pressure control system, the method provided in the present embodiment changes the frequency of the actuator of the pressure regulating valve in advance, thereby realizing control optimization. The input-output negative feedback characteristic of the pressure control system refers to a process characteristic that a pressure of the system is changed along with pressure setting within a period of time under the condition of fixed flow and is finally stabilized at a set pressure value, and a final stable state of the system is that the detected pressure is equal to the set pressure.

A real-time state is determined according to a relationship between the actually measured actual pressure in the chamber and the set target pressure, and the frequency of the motor is changed based on the negative feedback characteristic, thereby changing a pressure control parameter. Moreover, the frequency of the actuator is calculated according to different pressure differences, so that fine adjustment to the opening of the pressure regulating valve can be performed, thereby achieving the purpose of controlling the pressure rapidly and stably.

In a preferred embodiment, at step S3, controlling the frequency of the actuator to decrease according to the preset functional relationship specifically includes:
calculating a difference between each acquired actual pressure value and the target pressure value; and
in a case where the difference is greater than zero (that is, the actual pressure value does not reach the target pressure value), controlling the frequency of the actuator to decrease according to the preset functional relationship, with the preset functional relationship meeting that the differences corresponding to all the actual pressure values correspond to frequencies of the actuator in a one-to-one correspondence manner.

Optionally, the second actual pressure value is acquired after and adjacent to the first actual pressure value. In a case where the pressure variation is greater than zero, as the difference between the actual pressure value and the target pressure value decreases, the frequency of the actuator is reduced according to the preset functional relationship. Specifically, the actual pressure value in the process chamber which is measured in real time is compared with the preset target pressure value, and the frequency of the actuator is adjusted according to the real-time difference between the actual pressure value and the target pressure value. Specifically, the frequency of the actuator is continuously reduced as the difference between the real-time pressure measurement value and the set pressure value decreases. In a process of the actually measured actual pressure value P1 reaching the preset target pressure value Pn, ΔP1=Pn−P1, and ΔP1 corresponds to one frequency of the actuator; and for the actual pressure value P2, ΔP2=Pn−P2, and ΔP2 corresponds to another frequency of the actuator, with P1 and P2 being two adjacent pressure values measured in real time, until the difference ΔP=0. Each pressure difference corresponds to one frequency, the frequency is changed linearly, and a change of the frequency of the actuator may change a movement rate of the pressure regulating valve, and the movement rate of the pressure regulating valve specifically refers to a movement rate of the motor driving the valve.

With the pressure control method, frequency conversion is automatically sub-divided step by step along with a pressure setting point (the target pressure value), that is, during the closed-loop control process, according to the difference between the actual pressure and the set pressure, frequency conversion control of the motor is performed according to a set pressure variation threshold, a movement speed of the motor becomes lower as the actual pressure approaches the pressure setting point, thereby making the pressure stable. In this way, the pressure overshoot can be effectively avoided during the pressure control process, and a process effect can be improved.

It should be noted that the control method provided in the present embodiment is also applicable to other pressure control modes in which closed-loop control is performed based on a difference.

In the present embodiment, the pressure regulating valve may be a piston valve, a butterfly valve, a needle valve, or a ball valve.

The chamber pressure control method provide in the present embodiment is further explained below by taking the piston valve as an example.

In a process of controlling the piston valve, a position of the piston valve is basically adjusted by use of an aerodynamic bearing and force balancing. When a certain threshold is reached, motor drive does not function, and the piston valve may be mechanically adjusted by automatic expansion and contraction of a spring, thereby performing pressure control rapidly and stably.

Taking the piston valve as an example, since a pressure response usually has certain hysteresis in the pressure control system, especially in a chamber with a relatively large volume, in order to better highlight a control effect, buffer hysteresis compensation control (adjustment solely by mechanical elasticity) is added on the basis of frequency conversion control, thereby making the control effect better.

As shown in FIG. 2, the abscissa represents time, the ordinate represents pressure, and P1 is a set target pressure value. In a process of an actually detected chamber pressure approaching the pressure setting, the frequency of the actuator (the motor) is reduced as the difference between the detected actual pressure value in the process chamber and the set target pressure value decreases. The gradual increase from t1 to tn in FIG. 2 represents that the frequency of the actuator becomes smaller and smaller.

The initial frequency F₁ of the actuator is a fixed maximum value (the maximum value with which the actuator system does not produce resonance), and is limited by the pressure system. Fᵢ₊₁=K×Fᵢ, where Fᵢ is the current frequency of the actuator, Fᵢ₊₁ is a next frequency of the actuator, the value of K is between 0 and 1, i=1, 2, 3, . . . , n, and F₁ is the initial frequency. The value of K may be set according to actual needs, for example, K=0.1. When a frequency conversion condition is triggered, for example, when a certain proportion of the difference between the measured actual pressure value and the set target pressure value is reached, a frequency conversion process is performed. For example, the certain proportion is 5%, that is, a pressure difference needs to be changed by more than 5% for a next frequency conversion process to be performed. The frequency conversion degree may be adjusted according to actual situations, for example, the frequency is changed to 10% of a previous frequency each time, thereby being reduced step by step.

When the gas flow in the pressure control system of the process chamber is continuously and gradually reduced or increased within a specified period of time, a fluctuation in the pressure in the chamber may be caused. As long as the actual pressure in the chamber is different from the set pressure, the actuator performs frequency conversion, and changes the frequency step by step along with the decrease of the difference between the actual pressure in the chamber and the set target pressure, so as to gradually reduce a movement rate of the valve of the pressure regulating valve, thereby avoiding the problem of pressure overshoot and reducing the influence of the pressure fluctuation on the process.

In summary, the chamber pressure control method provided in the present disclosure can reduce the pressure overshoot phenomenon caused by a pressure change or a flow change, and realize quick pressure control response and stable pressure control. The chamber pressure control method provided in the present disclosure is not limited to the semiconductor field, and can be also applied to other pressure control fields, such as the photovoltaic field.

### Embodiment Two

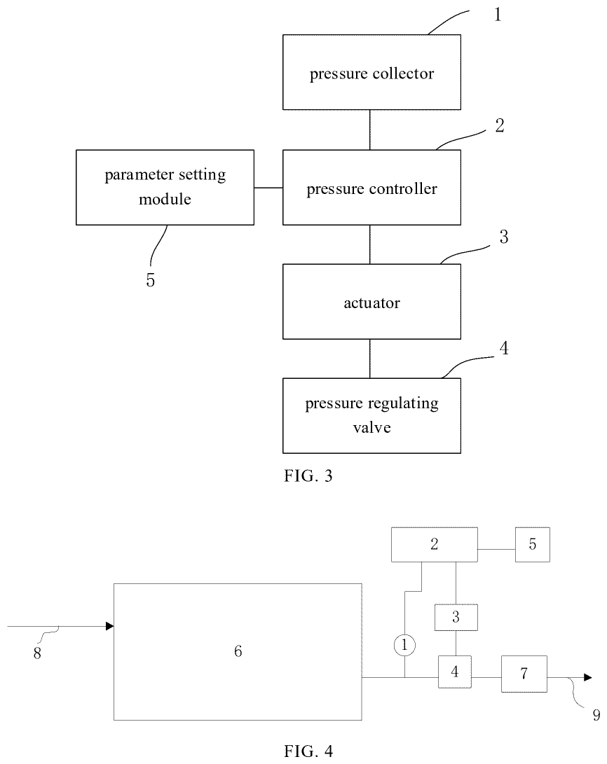

As shown in FIG. 3, a chamber pressure control apparatus includes: a pressure collector 1, a pressure controller 2, and an actuator 3.

The pressure collector 1 is configured to collect an actual pressure value in a process chamber in real time.

The pressure controller 2 is configured to perform the chamber pressure control method provided in Embodiment One.

The actuator 3 is configured to control an opening change of a pressure regulating valve 4 based on a frequency output by the pressure controller 2.

In the present embodiment, the chamber pressure control apparatus further includes a parameter setting module 5, which is configured to set a target pressure value of the chamber and a calculation function for actuator frequency.

In the present embodiment, the actuator 3 is a motor for controlling the opening change of the pressure regulating valve 4, and a frequency of the actuator 3 is a rotation frequency of the motor.

In the present embodiment, the pressure regulating valve 4 is a piston valve, a butterfly valve, a needle valve, or a ball valve.

Preferably, the pressure regulating valve includes an elastic telescopic member, so as to perform opening adjustment with the elastic telescopic member. For example, the pressure regulating valve is a piston valve with a spring. In a process of controlling the piston valve, a position of the piston valve is basically adjusted by use of an aerodynamic bearing and force balancing. When a certain threshold is reached, motor drive does not function, and the piston valve may be mechanically adjusted by automatic expansion and contraction of a spring, thereby performing pressure control rapidly and stably.

With the chamber pressure control apparatus provided in the present embodiment, when an actual pressure in the chamber is different from a set pressure, the pressure controller adopts the chamber pressure control method provided in Embodiment One to perform closed-loop control, and controls the actuator 3 to perform frequency conversion to change the frequency step by step along with a decrease of a difference between the actual pressure value in the process chamber and the set target pressure value, so as to gradually reduce a movement rate of a valve of the pressure regulating valve, thereby avoiding the problem of pressure overshoot and reducing the influence of the pressure fluctuation on the process to the greatest extent.

### Embodiment Three

As shown in FIG. 4, a semiconductor process device includes a process chamber 6, and further includes the chamber pressure control apparatus provided in Embodiment Two.

In the present embodiment, one end of the process chamber 6 is connected to a gas intake pipeline 8, the other end of the process chamber 6 is connected to an exhaust pipeline 9, the exhaust pipeline 9 is provided with the pressure collector 1, the pressure regulating valve 4, and a vacuum extraction device 7, the pressure regulating valve 4 is connected to the actuator 3, and the pressure collector 1, the actuator 3, and the parameter setting module 5 are respectively connected to the pressure controller 2.

By adopting the chamber pressure control apparatus provided in Embodiment Two, the semiconductor process device provided in the present embodiment can control a chamber pressure rapidly and stably, and avoid the problem of pressure overshoot, thereby improving process quality and yield.

The embodiments of the present disclosure are described above, but the above description is illustrative rather than exhaustive, and the present disclosure is not limited to the disclosed embodiments. Many modifications and changes are apparent to those of ordinary skill in the art without departing from the scope and spirit of the embodiments of the present disclosure.

1. A pressure control method applied to a process chamber of a semiconductor process device, a gas pipeline of the process chamber being provided with a pressure regulating valve for regulating a pressure in the process chamber, wherein the method comprises:
acquiring an actual pressure value in the process chamber in real time;
calculating a pressure variation of the actual pressure value; and
comparing the pressure variation with a preset value set in advance; in a case where the pressure variation is less than or equal to the preset value, controlling an actuator of the pressure regulating valve to maintain a current frequency, and controlling an opening change of the pressure regulating valve based on the current frequency; and in a case where the pressure variation is greater than the preset value, controlling a frequency of the actuator to decrease according to a preset functional relationship, and controlling the opening change of the pressure regulating valve based on the frequency.

2. The pressure control method of claim 1, wherein calculating the pressure variation of the actual pressure value comprises:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to a maximum difference between an initial actual pressure value in the process chamber and the target pressure value as the pressure variation.

3. The pressure control method of claim 1, wherein calculating the pressure variation of the actual pressure value comprises:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to the first difference as the pressure variation.

4. The pressure control method of claim 1, wherein controlling the frequency of the actuator to decrease according to the preset functional relationship comprises:
calculating a difference between each acquired actual pressure value and a target pressure value; and
in a case where the difference is greater than zero, controlling the frequency of the actuator to decrease according to the preset functional relationship, with the preset functional relationship meeting that differences corresponding to all actual pressure values correspond to frequencies of the actuator in a one-to-one correspondence manner.

5. The pressure control method of claim 1, wherein the preset functional relationship is: [symbol] , where Fᵢ is the current frequency of the actuator, Fᵢ₊₁ is a next frequency of the actuator, a value of K is between 0 and 1, and i=1, 2, 3, . . . , n, wherein F₁ is an initial frequency of the actuator, and the initial frequency is a maximum frequency at which the actuator does not produce resonance.

6. The pressure control method of claim 5, wherein controlling the opening change of the pressure regulating valve based on the frequency comprises:
according to the acquired actual pressure value and a target pressure value set in advance, controlling the opening change of the pressure regulating valve with a Proportional-Integral-Derivative (PID) closed-loop control method.

7. The pressure control method of claim 1, wherein the actual pressure value is an absolute pressure value inside the process chamber; or
the actual pressure value is a relative value between the pressure inside the process chamber and the atmospheric pressure.

8. A chamber pressure control apparatus, comprising: a pressure collector, a pressure controller, and an actuator;
the pressure collector is configured to collect an actual pressure value in a process chamber in real time;
the pressure controller is configured to perform the pressure control method of claim 1; and
the actuator is configured to control an opening change of a pressure regulating valve based on a frequency output by the pressure controller.

9. The chamber pressure control apparatus of claim 8, wherein the actuator is a motor for controlling the opening change of the pressure regulating valve, and a frequency of the actuator is a rotation frequency of the motor.

10. The chamber pressure control apparatus of claim 8, wherein the pressure regulating valve comprises an elastic telescopic member, so as to perform opening adjustment with the elastic telescopic member.

11. A semiconductor process device, comprising a process chamber, and a pressure regulating valve provided on a gas pipeline of the process chamber, wherein the semiconductor process device further comprises the chamber pressure control apparatus of claim 8.

12. The chamber pressure control apparatus of claim 8, wherein calculating the pressure variation of the actual pressure value comprises:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to a maximum difference between an initial actual pressure value in the process chamber and the target pressure value as the pressure variation.

13. The chamber pressure control apparatus of claim 8, wherein calculating the pressure variation of the actual pressure value comprises:
calculating a first difference between a first actual pressure value in the process chamber which is acquired at a first moment and a target pressure value;
calculating a second difference between a second actual pressure value in the process chamber which is acquired at a second moment and the target pressure value; and
calculating a ratio of a difference between the first difference and the second difference to the first difference as the pressure variation.

14. The chamber pressure control apparatus of claim 8, wherein controlling the frequency of the actuator to decrease according to the preset functional relationship comprises:
calculating a difference between each acquired actual pressure value and a target pressure value; and
in a case where the difference is greater than zero, controlling the frequency of the actuator to decrease according to the preset functional relationship, with the preset functional relationship meeting that differences corresponding to all actual pressure values correspond to frequencies of the actuator in a one-to-one correspondence manner.

15. The chamber pressure control apparatus of claim 8, wherein the preset functional relationship is: [symbol] , where Fᵢ is the current frequency of the actuator, Fᵢ₊₁ is a next frequency of the actuator, a value of K is between 0 and 1, and i=1, 2, 3, . . . , n, wherein F₁ is an initial frequency of the actuator, and the initial frequency is a maximum frequency at which the actuator does not produce resonance.

16. The pressure control method of claim 15, wherein controlling the opening change of the pressure regulating valve based on the frequency comprises:
according to the acquired actual pressure value and a target pressure value set in advance, controlling the opening change of the pressure regulating valve with a Proportional-Integral-Derivative (PID) closed-loop control method.

17. The chamber pressure control apparatus of claim 8, wherein the actual pressure value is an absolute pressure value inside the process chamber; or
the actual pressure value is a relative value between the pressure inside the process chamber and the atmospheric pressure.

18. The semiconductor process device of claim 11, wherein the actuator is a motor for controlling the opening change of the pressure regulating valve, and a frequency of the actuator is a rotation frequency of the motor.

19. The semiconductor process device of claim 11, wherein the pressure regulating valve comprises an elastic telescopic member, so as to perform opening adjustment with the elastic telescopic member.
